(19) United States
(12) Patent Application Publication
(10) Pub. No.: US 2016/0057891 A1
(43) Pub. Date: Feb. 25, 2016

(54) HEAT SINK AND METHOD OF ASSEMBLYING

(71) Applicant: SCHNEIDER ELECTRIC USA, INC., Palatine, IL (US)

(72) Inventors: Yi-Ching Chang, New Taipei City (TW); Shen-Yuan Chien, Taipei City (TW)

(21) Appl. No.: 14/888,229

(22) PCT Filed: May 3, 2013
(86) PCT No.: PCT/US13/39451

§ 371 Date: Oct. 30, 2015

(51) Int. Cl. H05K 7/20; B23P 15/26

(52) U.S. Cl. CPC H05K 7/20409; B23P 15/26

(57) ABSTRACT

A heat sink assembly includes a heat sink configured to be attached to an electronic assembly and to secure at least one component package thereto, a clip configured to be secured to the heat sink and to secure the component package to the heat sink, and at least one fastener to secure the clip to the heat sink. A method for assembling a heat sink assembly includes securing an component package to a heat sink with a clip, and securing the heat sink to an electronic substrate.

### BACKGROUND

1. Field of Disclosure

The present disclosure relates generally to the field of electronics and, more particularly, to devices and methods that dissipate heat from electronic components.

2. Discussion of Related Art

Modern electronic components produce excessive amounts of heat during operation. To ensure that the components do not overheat, system designers attach convective heat sinks to cool these components, by providing an efficient heat transfer path from the devices to the environment. A typical convective heat sink is designed to transfer heat energy from the high temperature component to lower temperature of the surrounding air. Such typical heat sinks attach to the components through a base and include fins or pins to increase the surface area of the heat sink within a given space.

When securing transistors and/or diodes on a heat sink, it is desirable to ensure these components are tightly attached on heat sink for good heat conduction, and to ensure that the heat sink assembly is tightly secured on a substrate, such as a printed circuit board (“PCB”). It is further desirable for a quicker and easier assembly process in production or product repair, especially since existing assembly designs are somewhat complicated.

With prior art assembly methods, there are often too many screws and individual clips that are used to secure the components to the heat sink, which result in higher material and production cost. For example, with the heat sink 10 shown in FIG. 1, there are ten transistors and/or diodes, each indicated at 12, attached on a heat sink with six clips, each indicated at 14, and ten screws, each indicated at 16.

When securing a heat sink to a PCB, especially for heavy heat sinks, the heat sink is secured to the PCB from a bottom side of the PCB. FIGS. 2A-2D illustrate an overturn process that is known to secure a heat sink 20 to a PCB 22. As shown, the overturn process can be complicated in that a customized jig 24 is provided to hold the PCB 22 in place during the process.

In addition, as shown in FIG. 3, screws that are used to secure transistors and/or the clips usually cannot be removed from a completed PCB assembly 30 having a PCB 32, heat sinks, each indicated at 34, and large components, each indicated at 36. The large components 36 are located near the screws that block the way to unscrew heat sinks 34 from the PCB 32. In general, a technician disassembling the heat sinks 34 needs to unsolder all of the large components 36 located near the heat sinks, or unsolders all of the transistors on the heat sinks, and then detaches the full heat sink assembly from the PCB 32. This process takes time and effort in PCB assembly repair in replacing transistors and/or diodes.

### SUMMARY OF DISCLOSURE

One aspect of the disclosure is directed to a heat sink assembly comprising a heat sink configured to be attached to an electronic assembly and to secure at least one component package thereto, a clip configured to be secured to the heat sink and to secure the component package to the heat sink, and at least one fastener to secure the clip to the heat sink.

Embodiments of the heat sink assembly may include a bracket configured to be secured to the electronic substrate and to secure the heat sink to the electronic substrate. In one embodiment, the bracket may be square-shaped in cross-section, with the bracket including at least one retention member to axially secure the bracket to the electronic substrate. The bracket may include a threaded opening formed therein. The heat sink may be configured with an opening formed in a first fin of the heat sink and a cutout formed in a second fin of the heat sink located above the first fin. The heat sink may include a flange secured to a wall of the heat sink in which the clip is configured to be received within the flange of the heat sink. The clip may include a channel portion that is received within the flange and a leg portion that engages the component package. The at least one fastener may include a screw fastener configured to be received within aligned openings formed in the flange of the heat sink and the channel portion of the clip. The leg portion may be bent relative to the channel portion to adjust an amount of force applied by the leg portion on the component package. The channel portion may be elongated to have two or more leg portions extending therefrom.

Another aspect of the disclosure is directed to a method for assembling a heat sink comprising securing an component package to a heat sink with a clip, and securing the heat sink to an electronic substrate.

Embodiments of the method may include adjusting a force applied by the leg portion on the component package. The method further may include securing additional component packages with the clip. Securing the heat sink to an electronic substrate may include positioning a bracket within an opening of the electronic substrate, with the bracket being configured to secure the heat sink to the electronic substrate. The bracket may be square-shaped in cross-section, with the bracket including at least one retention member to axially secure the bracket to the electronic substrate. The bracket may include a threaded opening formed therein. The heat sink may be configured with an opening formed in a first fin of the heat sink and a cutout formed in a second fin of the heat sink located above the first fin. The heat sink may include a flange provided on a wall of the heat sink, with the clip being configured to be received within the flange. The clip may include a channel portion that is received within the flange and a leg portion that engages the electronic substrate.

### BRIEF DESCRIPTION OF THE DRAWINGS

Various aspects of at least one embodiment are discussed below with reference to the accompanying figures, which are not intended to be drawn to scale. Where technical features in the figures, detailed description or any claim are followed by references signs, the reference signs have been included for the sole purpose of increasing the intelligibility of the figures, detailed description, and claims. Accordingly, neither the reference signs nor their absence are intended to have any limiting effect on the scope of any claim elements. In the figures, each identical or nearly identical component that is illustrated in various figures is represented by a like numeral. For purposes of clarity, not every component may be labeled in every figure. The figures are provided for the purposes of illustration and explanation and are not intended as a definition of the limits of the disclosure. In the figures:

FIG. 1 is a plan view of an exemplary heat sink having transistors and diodes mounted on the heat sink;

FIGS. 2A-2D are perspective views showing a prior art method of securing an assembled heat sink to a substrate, such as a PCB;

FIG. 3 is a view of a fully assembled PCB assembly having large components mounted on the substrate;

FIG. 4 is a perspective view of a heat sink assembly of the present disclosure;

FIG. 5 is an exploded perspective view of the heat sink assembly prior to mounting the heat sink assembly onto a substrate;

FIG. 6 is a perspective view of the heat sink and enlarged details of the heat sink;

FIG. 7 is a perspective view of a clip of the heat sink assembly with top, front, and side views for clarity;

FIGS. 8A and 8B are views of the clip securing a transistor and/or diode to the heat sink;

FIG. 9 is a perspective view of a fastener assembly of the heat sink assembly;

FIGS. 10A and 10B illustrate the heat sink being secured to the PCB with the fastener;

FIGS. 11-16 illustrate a sequence of assembling the PCB assembly;

FIG. 17 illustrates the repair of the PCB assembly;

FIG. 18 illustrates an alternative clip design; and

FIG. 19 is a perspective view of a heat sink assembly of another embodiment of the disclosure.

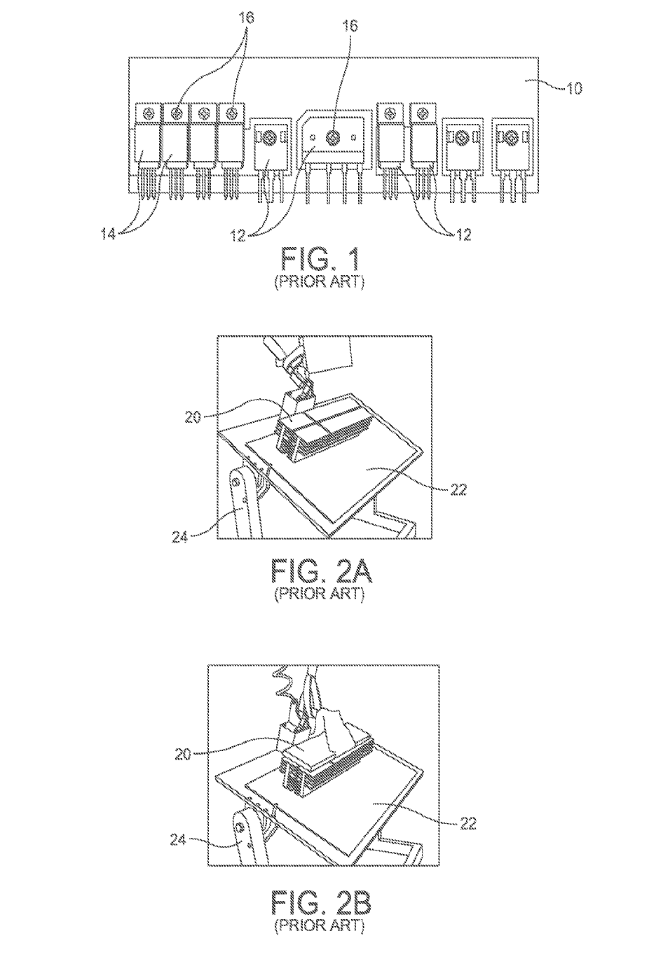

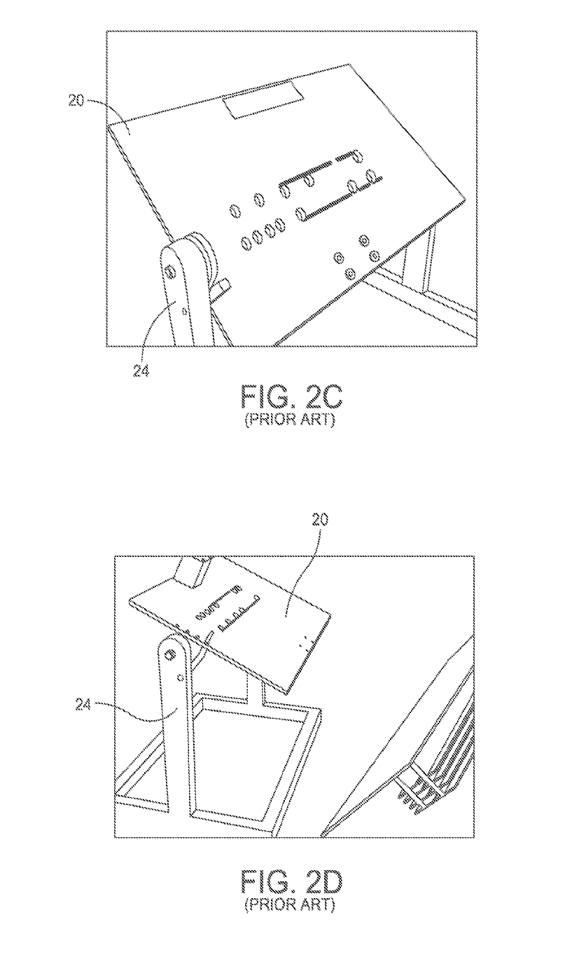

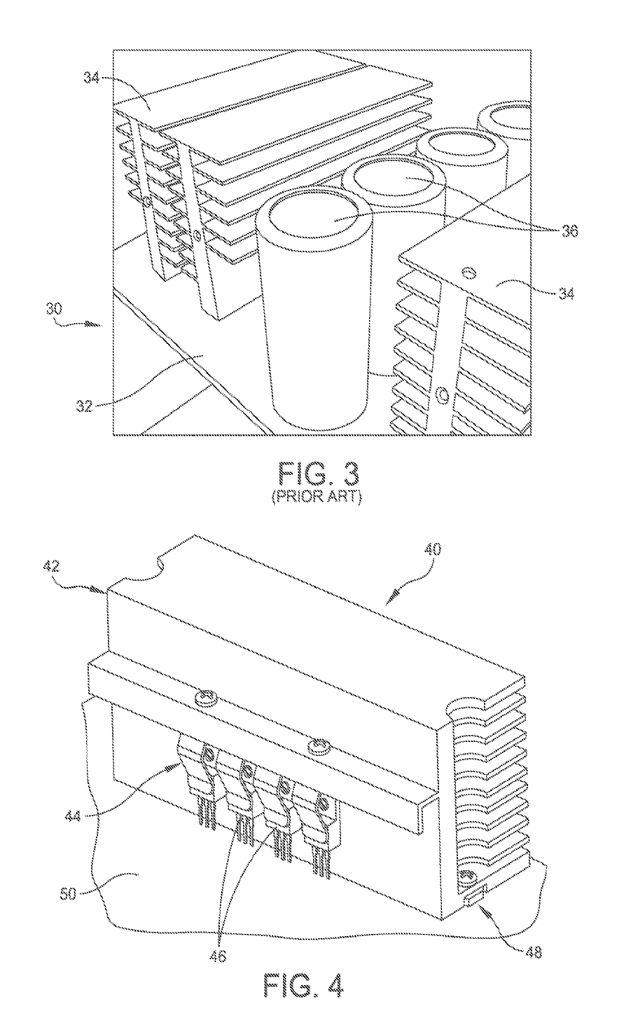

### DETAILED DESCRIPTION

As discussed above, traditional heat sinks suffer from several disadvantages, such as being increasingly large, heavy and costly. Accordingly, there is a need for a more efficient device, system and method of heat dissipation that would be lighter and easier to construct and assemble. Aspects and embodiments are directed to methods of fabricating heat dissipation devices that overcome the limitations and drawbacks of conventional solutions, while providing a solution that is functionally uncomplicated and easy to implement. As used herein, the term “heat-generating component” may refer to any electronic components or a group of components that generate heat, for example semiconductor devices, such as bipolar junction transistors, MOS-FETs, diodes or IGBTs, to name a few.

The present disclosure is directed to a heat sink assembly and method of assembling and installing the heat sink assembly that increases production efficiency and product reliability. For some kinds of transistor and/or diode packages, such as TO-220 or TO-247 component packages, a heat sink to help heat dissipation is often needed. Such transistors and/or diodes, sometimes referred to as component packages, are secured on the heat sink with a certain applied pressure. This may result in too many screws and/or individual clips being used to secure the component packages on heat sink, a troublesome PCB assembly overturn process to secure heat sink on PCB assembly in production, and very difficult to replace transistors/diodes in PCBA repair.

The present disclosure is directed to a heat sink assembly having a clip that can be used to secure component packages, such as transistors and/or diodes having different sizes, on heat sink with stable pressure and minimized screw quantity used to screw the clip. The design of the heat sink assembly of the present disclosure enables a fully top-down screw and unscrew operation for PCB assembly production and repair.

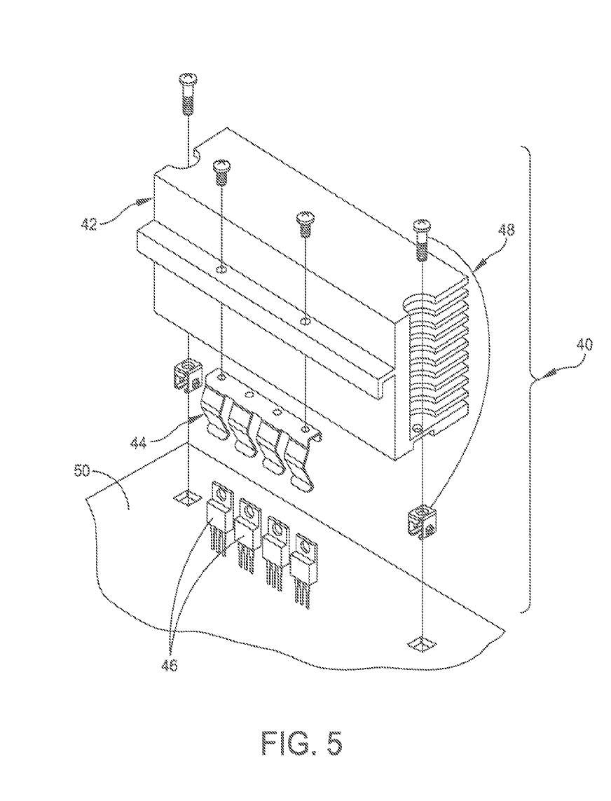

Referring now to the drawings, and more specifically to FIGS. 4 and 5, the heat sink assembly of the present disclosure is generally indicated at 40. In the shown embodiment, the heat sink assembly 40 includes a heat sink generally indicated at 42, a clip, generally indicated at 44, which are used to secure several component packages, each indicated at 46, to the heat sink, and two fastener assemblies, each generally indicated at 48, which are used to secure the heat sink to a substrate 50, such as a PCB. When assembling and installing the heat sink assembly 40, the component packages 46 are secured to the heat sink 42 by the clip 44, and the assembled heat sink is installed on the substrate 50 by the fastener assemblies 48.

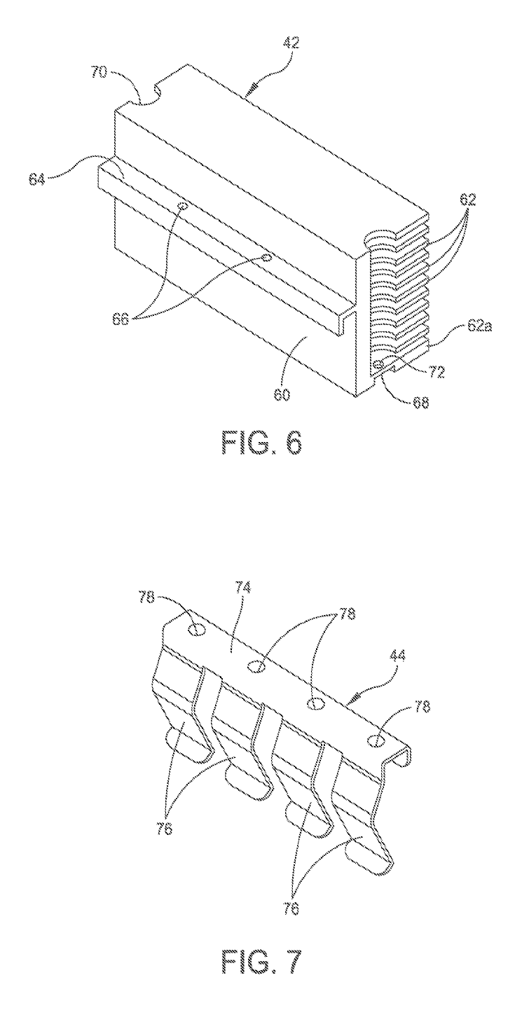

Referring to FIG. 6, as shown, the heat sink 42 includes an upright body portion 60 having a plurality of fins, each indicated at 62, which are spaced apart from one another and extend horizontally from the body portion. The number and spacing of the fins 62 may be selected based on the particular application. As shown, the bottom fin 62a is thicker in construction and is configured to engage a planar surface of the substrate. However, it should be noted that the bottom fin 62a may be the same or of a lesser thickness than the remaining fins 62. The heat sink 42 may be fabricated from an extrusion process with any suitable material, such as aluminum or aluminum alloys. The heat sink is of typical construction, with the fins 62 being provided to dissipate heat from the substrate 50 and the component packages 46.

In certain embodiments, the heat sink 42 is constructed with an additional component to secure the clip 44 to the heat sink. In one embodiment, the additional component is an L-shaped flange 64 having a first portion that extends away from the body portion of the heat sink 42 and a second portion that extends downwardly from the first portion toward the substrate 50. The first portion of the flange has two openings, each indicated at 66, formed therein. The flange 64 is sized to receive the 44 clip therein and configured to force the clip against the component packages to apply a desired amount of pressure against the component packages. A bottom surface of the bottommost fin 62a includes an extruded slot 68 formed therein to provide a space to accommodate two brackets of the fastener assemblies 48, which are used to secure the heat sink 42 to the substrate.

In further embodiments, the fins 62 of the heat sink 42 further include cutouts 70 that form two vertical slots on both ends of the heat sink to allow the heat sink to be screwed top-down onto the substrate through respective through holes 72 formed in the bottom fin 62a of the heat sink. These cutouts 70 (in half round shape) and through holes 72 are designed to require only one top-down fabrication setup on milling machine. The locations of the cutouts 70 may be provided at the ends of the heat sink 42 as shown in FIG. 6, or may be provided on a long side of the heat sink to secure the heat sink to the substrate 50.

As described, the clip 44 is secured to the heat sink 42 in the manner shown and described below, and is configured to apply a force to each component package 46 that is secured to the body portion 60 of the heat sink. Referring to FIG. 7, the clip 44 is formed as a specific shape to provide adequate force to each component package. As shown, the clip 44 includes a channel portion 74, which is sized to be received within the flange 64 of the heat sink 42, and several leg portions, each indicated at 76, that extend downwardly from the channel portion. The number and pitch of leg portions 76 may be varied depending on how many component packages need to be secured to the heat sink. As shown, four leg portions 76 are provided; however, the clip 44 can be designed to secure any number of component packages. The channel portion 74 includes four screw holes, each indicated at 78, which are provided to secure the clip 44 to the flange 64 of the heat sink 42 with suitable screw fasteners. More than two screw holes 78 are optional depending on actual application requirements and in some embodiments, only one screw hole is required. In one example, at least two screws holes 78 on both ends of the channel portion 74 of the clip 44 may be used to secure the clip to heat sink 42.

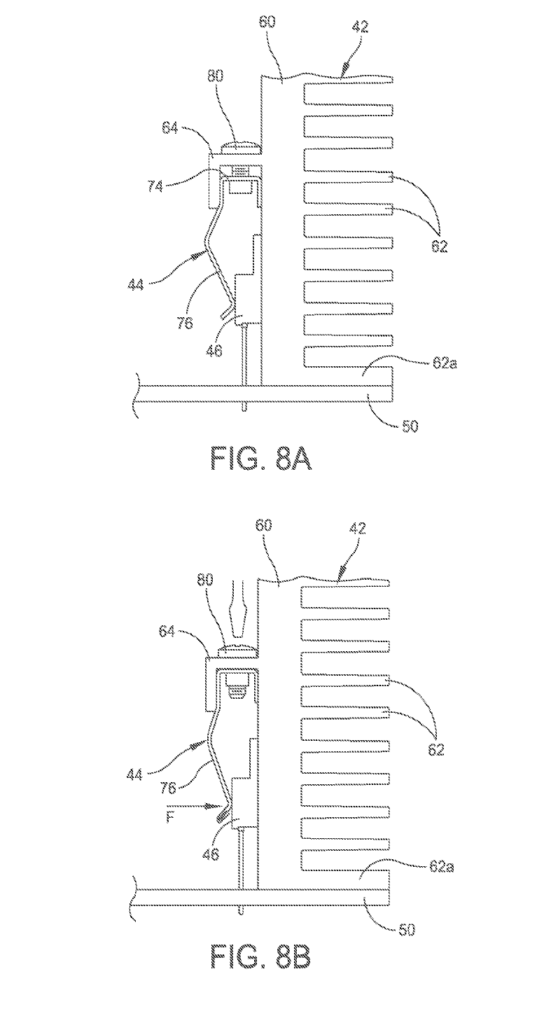

FIG. 8A illustrates the clip 44 prior to being fully secured to the flange 64 of the heat sink 42 with a screw fastener 80, which is inserted through the screw holes 78 (not designated in FIG. 8A) provided in the channel portion 74 of the clip. FIG. 8B illustrates a force indicated by arrow F being applied by the clip 44 against the component package 46 so that the component package is pressed against the body portion 60 of the heat sink 42. As described, the pressure or force applied to the component package 46 may be manipulated by the pitch or angle of the leg portion 76 of the clip 44 against the component package. One benefit of the design of the clip 44 is that the pressure applied by the leg portion 76 against the component package 46 is uniform and stable.

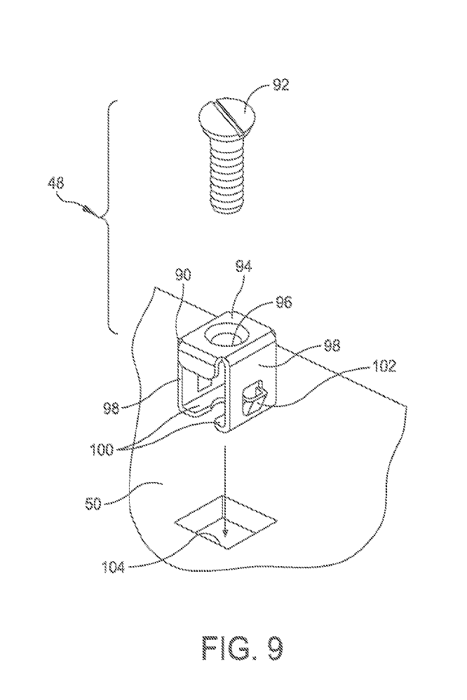

Referring to FIG. 9, each fastener assembly 48 includes a square-shaped bracket 90, which is secured to the substrate 50, and a screw fastener 92, which is threadably received by the bracket. The bracket 90 of the fastener assembly 48 is a special design to fasten relatively large and heavy components (e.g., heat sinks, conductors, capacitors, etc.) firmly on the substrate 50 from a top-down operation. As shown, the bracket 90 includes a top wall 94 having a threaded screw hole 96 formed therein and two downwardly extending side walls, each indicated at 98. Each side wall 98 has an inwardly extending portion 100 designed to capture an end of the screw fastener 92 when assembled. The side walls 98 each have a retention member 102 to axially secure the bracket 90 to the substrate 50 when placing the bracket within a square opening 104 formed in the substrate. The shapes of the bracket 90 and the opening 104 are square to more easily orient the assembly being mounted on the substrate 50. Other shapes may be selected to firmly secure and orient the bracket within its respective opening.

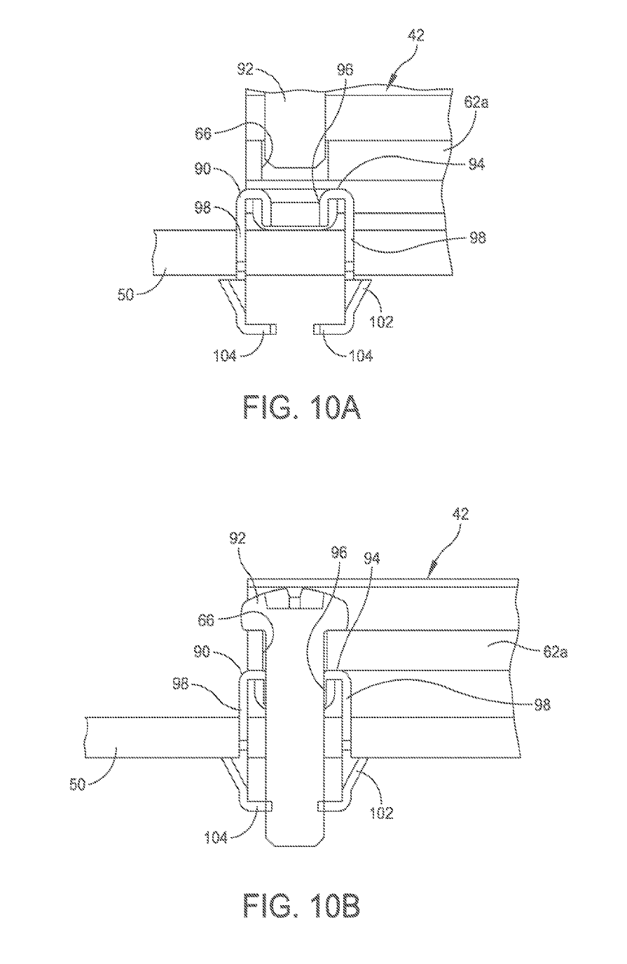

FIGS. 10A and 10B illustrate how the heat sink 42 is secured by the screw fastener 92 and the bracket 90 of the fastener assembly 48. Firstly, the bracket 90 is pressed and clipped into the square opening 104 of the substrate 50. Secondly, the screw fastener 92 extends through the opening 66 formed in the bottom fin 62a of the heat sink 42 and is threadably received by the threaded screw hole 96 of the bracket 90 of the fastener assembly 48. When screwing the screw fastener 92 into the bracket 90, the screw fastener pulls up the bracket to eliminate the gaps between the retention members 102 and the bottom surface of the bottom fin 62a of the heat sink 42 to tighten the heat sink in a z-axis direction. Furthermore, the inwardly extending portions 104 of the side walls 98 of the bracket 90 engage the screw fastener 92 to firmly seat the fastener assembly 48 and to prevent the screw fastener from being pulled out of the substrate 50.

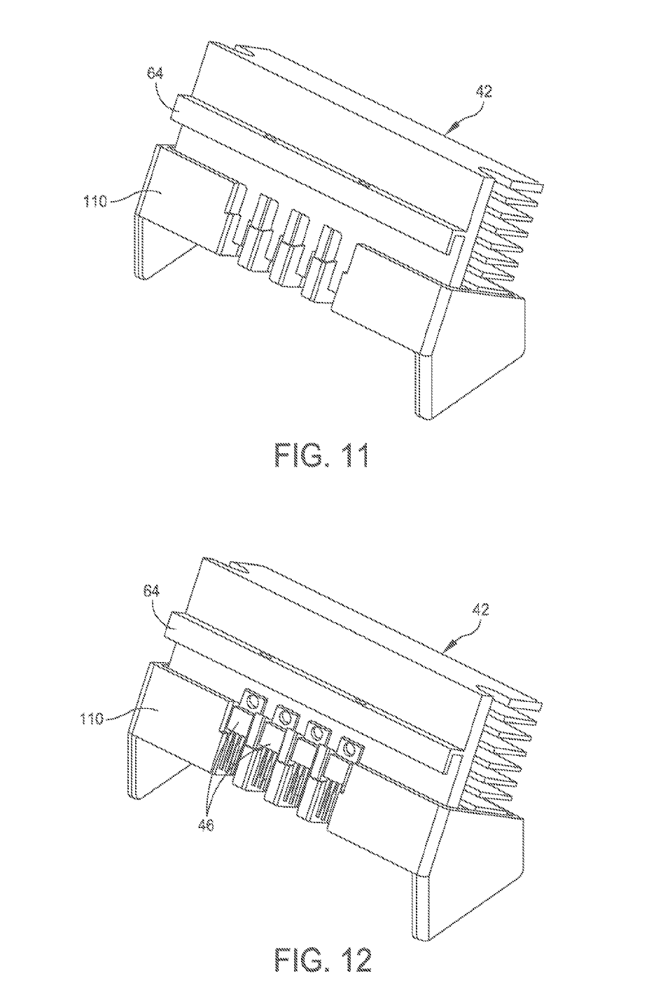

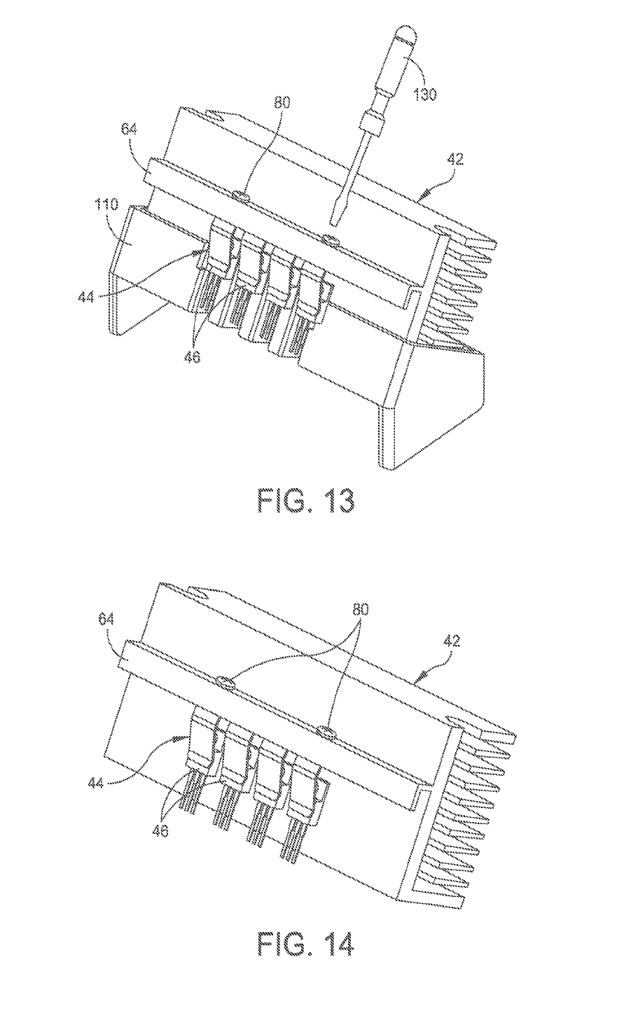

FIGS. 11-16 illustrate the assembly of the PCB assembly 30. The heat sink 42 is placed on a customized fixture 110 as shown in FIG. 11. The fixture 110 has a tilt to the ground as shown. The fixture 110 is designed to position component packages 46 and the clip 44 on the heat sink 42 based on the following steps. The component packages 46 are placed within slots provided within the fixture 110 in the manner shown in FIG. 12, and are maintained in position on the fixture due to gravity. The clip 44 is secured by holding the clip by hand in position over the component packages 46 and screwing the screw fastener 80 in the manner shown in FIG. 13 with a screwdriver 130 or some other implement. In the shown embodiment, as few as two screw fasteners 80 can be used as a default; however, the number of screw fasteners can be increased depending on the number of component packages 46 required to be secured to the heat sink 42. FIG. 14 shows the fully assembled heat sink 42 removed from the fixture 100.

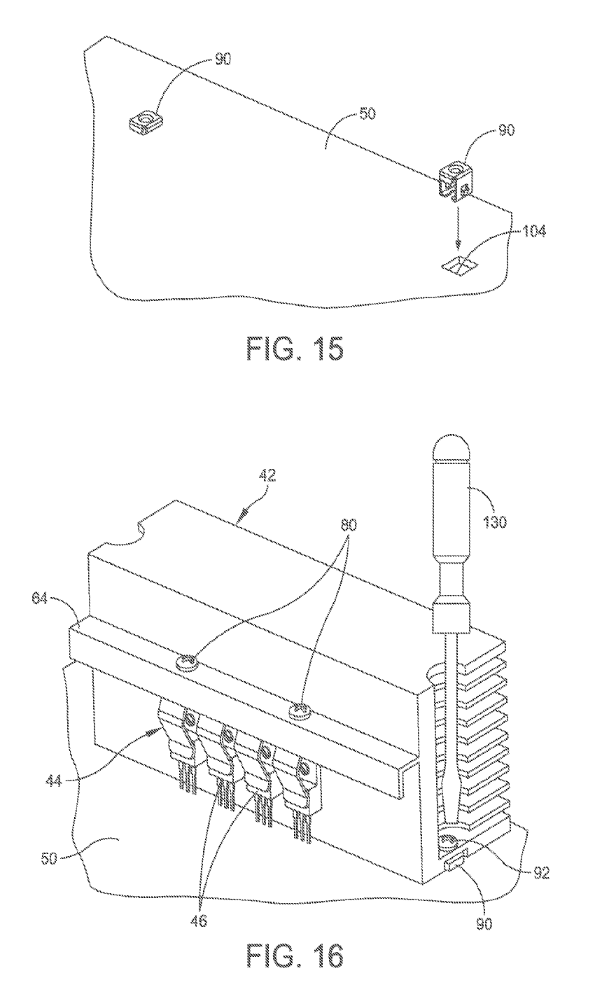

To secure the assembled heat sink 42 to the substrate 50, two brackets 90 of the fastener assemblies 48 are snapped on the substrate 50 within the two square openings 104 formed on the substrate as shown in FIG. 15. The leads of the component packages 46 are aligned with and inserted into openings formed in the substrate 50 when positioning the assembled heat sink 42 on the substrate. The heat sink 42 is secured to the substrate 50 by two screw fasteners 92 on both sides of the heat sink as shown in FIG. 16. As shown, the screwdriver 130 may be used to tighten the screw fasteners 92. The leads of the component packages 46 may be secured to the substrate 50 by wave soldering or some other appropriate technique.

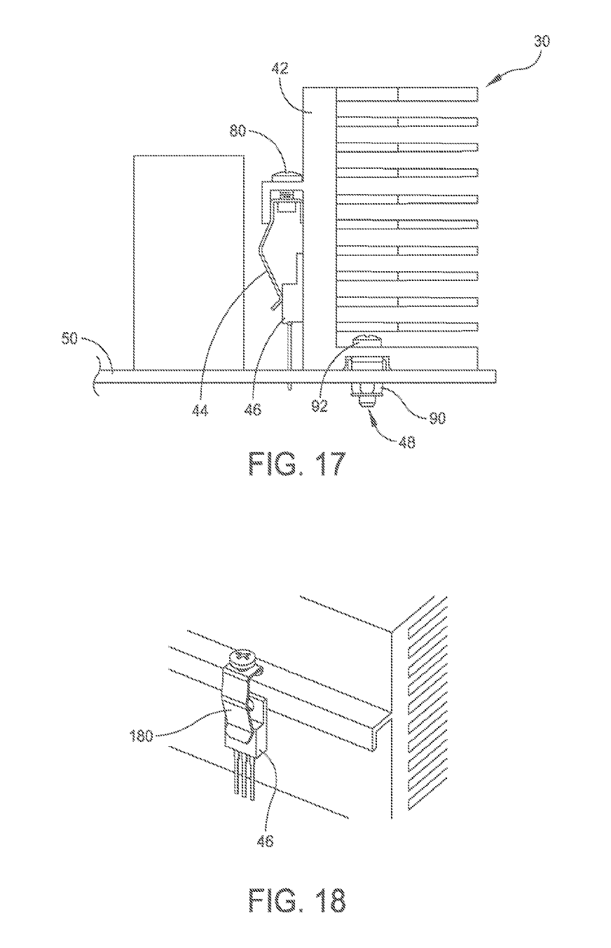

FIG. 17 illustrates an exemplary repair of a PCB assembly 30. In a first embodiment, when the component packages 46 are accessible on the PCB assembly 30, the repair process includes (a) unscrewing the screw fasteners 80 and removing the clip 44, (b) replacing the component packages 46, as required, and (c) re-securing the clip 44 and the screw fasteners 80. In a second embodiment, when the component packages 46 are not accessible in the PCB assembly 30, the repair process includes (a) partially loosening the screw fastener 80 until the clip 44 is loosened enough to disengage the component packages 46, with the heat sink 42, clip 44 and screw fasteners 80 being retained together as a partial heat sink assembly, (b) unscrewing the screw fasteners 92 of the fastener assemblies 48 completely to remove the partial heat sink assembly from the substrate 50, (c) replacing the component packages 46, (d) re-securing the partial heat sink assembly on the substrate 50, (e) screwing the screw fasteners 92 to secure the heat sink 42 to the substrate, and (f) fastening the screw fasteners 80 to secure the clip 44.

Referring to FIG. 18, alternatively, the clip 44 can be replaced by one or more individual clips 180, which are applied for single component packages 46. FIG. 18 illustrates a single clip 180 that is used to secure a single component package 46.

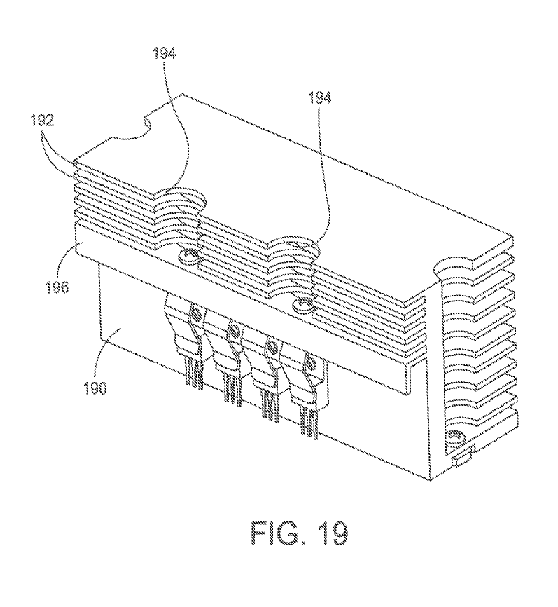

FIG. 19 illustrates a heat sink 190 having more fins 192 on a side of the heat sink having the clip 44. As shown, the fins 192 are configured with cutouts 194 that form slots in half-round shape, which can be fabricated with just one time of milling setup. The slots are used to secure the clip 44 to a flange 196 of the heat sink 190.

Thus, it should be observed that the methods for assembling heat sinks of the present disclosure produce heat sinks that are as efficient as heat sinks that are used with forced cooling. However, heat sinks produced in the manner disclosed herein are less expensive to make, and are more efficient. In addition, a single clip may be used to secure all component packages, even in different sizes, on a heat sink with stable pressure and minimized screw quantity, e.g., two fasteners, used to screw the clip. Moreover, a fully top-down screw/unscrew operation for heat sink assembly in PCB assembly production and repair.

It is to be appreciated that embodiments of the devices and methods discussed herein are not limited in application to the details of construction and the arrangement of components set forth in the following description or illustrated in the accompanying drawings. The devices and methods are capable of implementation in other embodiments and of being practiced or of being carried out in various ways. Examples of specific implementations are provided herein for illustrative purposes only and are not intended to be limiting. In particular, acts, elements and features discussed in connection with any one or more embodiments are not intended to be excluded from a similar role in any other embodiments.

Also, the phraseology and terminology used herein is for the purpose of description and should not be regarded as limiting. Any references to embodiments or elements or acts of the systems and methods herein referred to in the singular may also embrace embodiments including a plurality of these elements, and any references in plural to any embodiment or element or act herein may also embrace embodiments including only a single element. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. Any references to front and back, left and right, top and bottom, upper and lower, and vertical and horizontal are intended for convenience of description, not to limit the present systems and methods or their components to any one positional or spatial orientation.

Having thus described several aspects of at least one embodiment, it is to be appreciated various alterations, modifications, and improvements will readily occur to those skilled in the art. Such alterations, modifications, and improvements are intended to be part of this disclosure and are intended to be within the scope of the disclosure. Accordingly, the foregoing description and drawings are by way of example only, and the scope of the disclosure should be determined from proper construction of the appended claims, and their equivalents.

What is claimed is:

1. A heat sink assembly comprising:
a heat sink configured to be attached to an electronic assembly and to secure at least one component package thereto;
a clip configured to be secured to the heat sink and to secure the component package to the heat sink; and
at least one fastener to secure the clip to the heat sink.

2. The heat sink assembly of claim 1, wherein the heat sink includes a flange secured to a wall of the heat sink.

3. The heat sink assembly of claim 2, wherein the clip is configured to be received within the flange of the heat sink.

4. The heat sink assembly of claim 3, wherein the clip includes a channel portion that is received within the flange and a leg portion that engages the component package.

5. The heat sink assembly of claim 4, wherein the at least one fastener includes a screw fastener configured to be received within aligned openings formed in the flange of the heat sink and the channel portion of the clip.

6. The heat sink assembly of claim 4, wherein the leg portion is bent relative to the channel portion to adjust an amount of force applied by the leg portion on the component package.

7. The heat sink assembly of claim 4, wherein the channel portion is elongated to have two or more leg portions extending therefrom.

8. The heat sink assembly of claim 1, further comprising a bracket configured to be secured to the electronic substrate and to secure the heat sink to the electronic substrate.

9. The heat sink assembly of claim 8, wherein the bracket is square-shaped in cross-section, the bracket including at least one retention member to axially secure the bracket to the electronic substrate.

10. The heat sink assembly of claim 9, wherein the bracket includes a threaded opening formed therein.

11. The heat sink assembly of claim 8, wherein the heat sink is configured with an opening formed in a first fin of the heat sink and a cutout formed in a second fin of the heat sink located above the first fin.

12. A method for assembling a heat sink assembly comprising:
securing an component package to a heat sink with a clip; and
securing the heat sink to an electronic substrate.

13. The method of claim 12, wherein the heat sink includes a flange provided on a wall of the heat sink, the clip being configured to be received within the flange.

14. The method of claim 13, wherein the clip includes a channel portion that is received within the flange and a leg portion that engages the electronic substrate.

15. The method of claim 14, further comprising adjusting a force applied by the leg portion on the component package.

16. The method of claim 12, further comprising securing additional component packages with the clip.

17. The method of claim 12, wherein securing the heat sink to an electronic substrate includes positioning a bracket within an opening of the electronic substrate, the bracket being configured to secure the heat sink to the electronic substrate.

18. The method of claim 17, wherein the bracket is square-shaped in cross-section, the bracket including at least one retention member to axially secure the bracket to the electronic substrate.

19. The method of claim 18, wherein the bracket includes a threaded opening formed therein.

20. The method of claim 17, wherein the heat sink is configured with an opening formed in a first fin of the heat sink and a cutout formed in a second fin of the heat sink located above the first fin.
